(19) United States
(12) Patent Application Publication
(10) Pub. No.: US 2019/0212391 A1
(43) Pub. Date: Jul. 11, 2019

(54) METHOD FOR MONITORING A BATTERY

(71) Applicant: ROBERT BOSCH GMBH, Stuttgart (DE)

(72) Inventors: Oliver Dieter KOLLER, Weinstadt-Beutelsbach (DE); Patrick MUENZING, Fellbach (DE)

(73) Assignee: Robert Bosch GmbH, Stuttgart (DE)

(21) Appl. No.: 16/312,360

(22) PCT Filed: Apr. 27, 2017
(86) PCT No.: PCT/EP2017/060036

§ 371 Date: Dec. 21, 2018

(30) Foreign Application Priority Data
Jun. 30, 2016 (DE) 10 2016 211 898.6

(51) Int. Cl. G01R 31/36; G01R 31/367; G01R 31/392

(52) U.S. Cl. CPC G01R 31/3647; G01R 31/392; G01R 31/367

(57) ABSTRACT

A method and a system are presented for monitoring a battery in a motor vehicle. In the method, a first module ascertains operating quantities of the battery. Variables that represent the operating quantities are compared with a load capacity model in order to ascertain quantities characterizing the reliability of the battery, so that a future behavior of the battery can be predicted.

### FIELD OF THE INVENTION

The present invention relates to a method for monitoring a battery, in particular a battery in a motor vehicle, and to a system for carrying out the method.

### BACKGROUND INFORMATION

A vehicle electrical system is the totality of the electrical components or consumers of a motor vehicle. This network has the task of supplying energy to the electrical consumers. As energy storage devices in vehicle electrical systems, for example batteries are used. In today's vehicles, if the energy supply fails due to a fault in the vehicle electrical system or in a component of the vehicle electrical system, e.g. caused by aging, then important functions, such as power steering, may cease to operate. Because the steerability of the vehicle is not then incapacitated, but merely becomes stiffer, the failure of the vehicle electrical system is generally accepted in currently produced vehicles. In addition, in today's vehicles the driver is available as a fallback system.

However, it is to be noted that due to the increasing electrification of aggregates, as well as the introduction of new driving functions, greater demands are placed on the safety and reliability of the supply of electrical energy in the motor vehicle. In future highly automated driving functions, such as highway autopilot, the driver will be permitted to carry out, to a limited extent, activities not related to driving. This has the consequence that up until the termination of the highly automated driving function, the driver's function as a sensory, regulating, mechanical, and energetic fallback level will be limited.

For this reason, in highly automated driving the supply of electrical energy in order to ensure the sensory, regulating, and actuator-related fallback level has a safety relevance that was previously not known in motor vehicles. Faults or aging in the vehicle electrical system must therefore be recognized reliably and as completely as possible for the sake of product safety.

In order to enable prediction of component failure, reliability-based approaches for monitoring vehicle components have been developed. For this purpose, the vehicle electrical system components are monitored during operation, and any damage to them is ascertained.

German Published Patent Application No. 10 2013 203 661 describes a method for operating a motor vehicle having a vehicle electrical system. This vehicle electrical system has a semiconductor switch for which an actual state of load is ascertained on the basis of a determination of past load events. In the method, the load actually applied to the semiconductor switch is detected.

### SUMMARY

The presented method takes into account that in future automated and autonomous driving operation in the motor vehicle, the driver will no longer be available as a sensory, regulating, mechanical, and energetic fallback system as in the existing art. Rather, the vehicle will take over the functions of the driver, such as environmental recognition, trajectory planning, and trajectory implementation, which for example also include steering and braking.

If the supply of energy to the safety-relevant components fails, the vehicle can no longer be controlled by the highly or fully automated function, because all of the functions described above, such as environmental recognition and trajectory planning and implementation, are then no longer available. From the point of view of product safety, this places very high demands on the vehicle electrical system. This also means that the function of automated or autonomous driving must be made available to the user only when the vehicle electrical system is in a state of correct operation and will remain so at least in the near future.

The battery or batteries is/are one of the most important components in the vehicle energy network, ensuring the supply of energy in the vehicle. It has been recognized that due to this particular status in the vehicle electrical system, the analysis of the battery has to be expanded to include predictive approaches.

In an embodiment, the presented method can be divided into four modules that build on one another, which can be realized or implemented together, individually, or in any combination, for example in the battery sensor, in another control device, or in a comparable device, for example a cloud. The basic first module is here a precondition for all the other modules. These can be combined in any combinations with the first module. In the following, the named four modules are explained in more detail:

First module:

The task of the first module is to ascertain the load on the battery using the data of the battery sensor or a comparable device that is used to ascertain the battery quantities and/or to monitor its state, and to compare this with a load capacity model, whereby quantities characterizing the reliability of the battery can be ascertained.

Possible expansions are:
the implementation of boundary values of the reliability characteristic quantities, resulting in exchanging the battery, blocking operating modes, transition to a safe state and/or driver takeover;
further processing of the ascertained reliability characteristic values in order to ascertain the values characterizing system reliability, e.g. probability of vehicle electrical system failure; here as well, operating modes can be blocked, for example via boundary values, and/or the transition to the safe state and/or driver takeover can be initiated or triggered.

The second module, which is an expansion of the first module, has the following tasks, through an online prediction of the battery load:
granting authorizations for particular scenarios, such as operating modes or operating strategies,
selecting safe stop scenarios that can still be realized with the (aged) battery, and
predicting an exchange of battery, typically on the basis of previous load.

These data can be transmitted to a higher-level control device for further processing.

The third module, which is an expansion of the first module, has the task of adapting the load capacity model to the quality of the battery by comparing the load capacity model with the extrapolation of the actual SOH (state of health), characterized for example by loss of capacity. The load capacity model is subject to statistical scatter. Through comparison with the ascertained SOH, the quality of the battery, or the shift in the load capacity model, can be taken into account.

The fourth model, which is an expansion of the first model, has the task of comparing the SOH and the load previously experienced by the battery with central databases, such as a cloud, in order to:
improve the load capacity models on the basis of the multiplicity of batteries in the field;
enable online adaptation of the load capacity models in the vehicle; and
enable better design of future components/systems in the vehicle.

Up to now, known methods have not included a system controlling that carries out a total status monitoring of all relevant components or vehicle functions in the vehicle. From the point of view of product safety, such a system appears to be required for new safety-critical applications having different basic assumptions, such as automated driving.

It is to be noted that component failure due to wear is the fundamental cause of a large number of vehicle network states that are safety-relevant in the context of new areas of application. Therefore, such failures must be preventively identified, and countermeasures must be introduced, in the vehicle. Because the battery is one of the most important components in the vehicle energy network, in the present application measures are presented for preventive battery analysis that are indispensable for the realization of the new applications.

The presented method and the described system have, at least in some embodiments, a series of advantages, stated below:
Support for authorization and authorization decision for automated driving functions:

Aging effects, or the exceeding of a specified, accepted degree of aging in the battery, result in the withdrawal of authorization for, or the cessation of, driving functions such as automated driving, or the withdrawal of authorization for, or cessation of, particular operating modes, e.g. coasting, or a transition to the safe state in order to avoid safety-critical states.
Increase of reliability through adapted driving strategies:

Driving situations that cause too much aging of the battery during operation are avoided if this is possible from the system point of view.
Increase of availability:

Preventive battery exchange can be carried out in good time before an uncontrolled battery failure, for example at regular maintenance intervals.
Increase in safety when transitioning from automated driving operation to manual driving operation:

Through early warning before a battery failure, the transition of the vehicle to a situation that is easier for the driver to control can be carried out.
Mandatory necessity of bringing the vehicle to a safe state even when there is component failure without driver intervention during fully automated driving:

Gain of time in the introduction of the fallback strategy through early warning, or no authorization of driving functions when battery failure is imminent, and avoiding an undesired vehicle electrical system failure by checking which safe stop scenario is still permissible from the point of view of the battery.
Increasing the reliability and safety of non-automated vehicles as well, through early recognition of impending failures:

In this way, impaired/“limping” cars on roadways can also be avoided.

As already stated, it has been recognized that for automated or autonomous vehicles it is essential to predict the future behavior of safety-relevant components, as well as ascertaining their current state. In order to enable evaluation and prediction of the state of the vehicle energy network as a basis for all safety-relevant vehicle functions, prediction units are necessary for each component. The presented method provides the necessary procedure for the analysis of the battery, which is considered an important component of the vehicle energy network. A possible embodiment of the method is sketched in the following, in steps and with associated effects or advantages:
The battery sensor, or a comparable device used to ascertain battery quantities and/or to monitor the battery state, communicates load-relevant characteristic quantities, recorded at times of the respective measurements, such as SOC (state of charge) and temperature. Each characteristic quantity is thereby assigned to a time.
From the load-relevant characteristic quantities, the method ascertains the load previously seen, and, in combination with the load capacity, reliability characteristic quantities of the battery, such as probability of failure, are calculated.
On the basis of the prediction of the reliability characteristic quantities, the method is able to further identify possible safe stop scenarios, taking into account vehicle electrical system errors and operating strategies.
On the basis of the prediction of the reliability characteristic quantities, the method is able to grant, grant for a limited time, or prevent authorizations of operating modes, taking into account operating strategies.
On the basis of the prediction of the reliability characteristic quantities, the method is suitable for making a timely transition to the safe state when there is an impending battery failure.
On the basis of the prediction of the reliability characteristic quantities, the method is able to predict the failure of the battery and thus to plan a timely change of battery.
The method is suitable for optimizing the predictive model of the battery via its actual aging, ascertained for example in the battery sensor.
The method communicates the calculated data to a central data storage unit, thus enabling a further optimization of the predictive model.

Further advantages and embodiments of the present invention result from the description and the accompanying drawings.

It will be understood that the features named above and explained below may be used not only in the respectively indicated combinations, but also in other combinations, or by themselves, without going beyond the scope of the present invention.

### BRIEF DESCRIPTION OF THE DRAWINGS

FIG. 1 shows, in a block diagram, a battery sensor according to the existing art.

FIG. 2 shows, in a block diagram, a battery sensor for carrying out the method.

FIG. 3 shows, in a flow diagram, steps that are carried out one after the other in the algorithm of an embodiment of the presented method.

FIG. 4 shows a graphic of a Wöhler curve.

FIG. 5 shows a graphic of the Weibull distribution.

### DETAILED DESCRIPTION

The present invention is shown schematically in the drawings on the basis of specific embodiments, and is described in detail below with reference to the drawings.

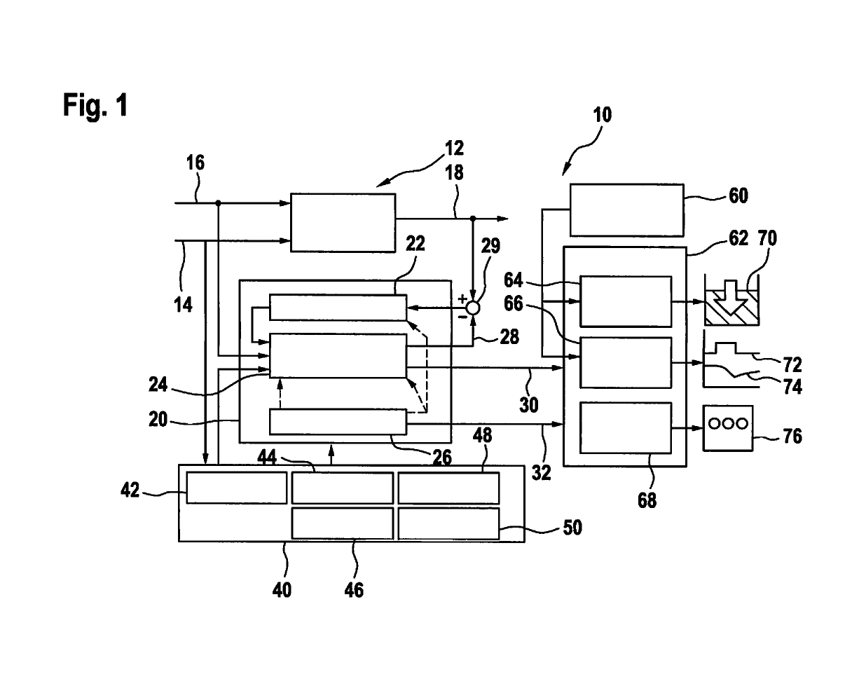

FIG. 1 shows a battery sensor known from the existing art, designated as a whole by reference character 10. Input quantities to a unit 12, in particular a measurement unit, are temperature T 14 and current I 16; the initial quantity is voltage U 18.

In a block 20, the estimation is carried out of parameters and states. In this block, a feedback unit 22, a battery model 24, and an adaptation 26 of the parameters are provided. A variable û 28, state variables ^{∧}x 30 and modeling parameters ^{∧}p 32 are outputted.

A node 29 is used to adapt battery model 24 to the battery. Current I 16 goes directly into battery model 24, and temperature T 14 goes indirectly into this model. This model calculates a 28 and compares it to the real voltage U 18. If there are deviations, battery model 24 is corrected via feedback unit 22.

In addition, a block 40 for sub-algorithms is provided. This block includes a battery temperature model 42, an open-circuit voltage 44, a peak voltage measurement 46, an adaptive starting current prediction 48, and a battery quantity acquisition unit 50.

In addition, charge profiles are provided that go into a block 62 that has predictors. These are a charge predictor 64, a voltage predictor 66, and an aging predictor 68. The outputs of block 62 are an SOC 70, curves of current 72 and voltage 74, and an SOH 76.

Battery sensor 10 thus ascertains the current SOC (state of charge) 70 of the battery and the current SOH 76 (state of health; loss of capacity compared to the initial state) of the battery. Via predictors 64, 66, 68, battery sensor 10 is able to predict SOC 70 and SOH 76 in accordance with a plurality of previously defined load scenarios. These can now also be adapted to automated driving or to the particular case of application.

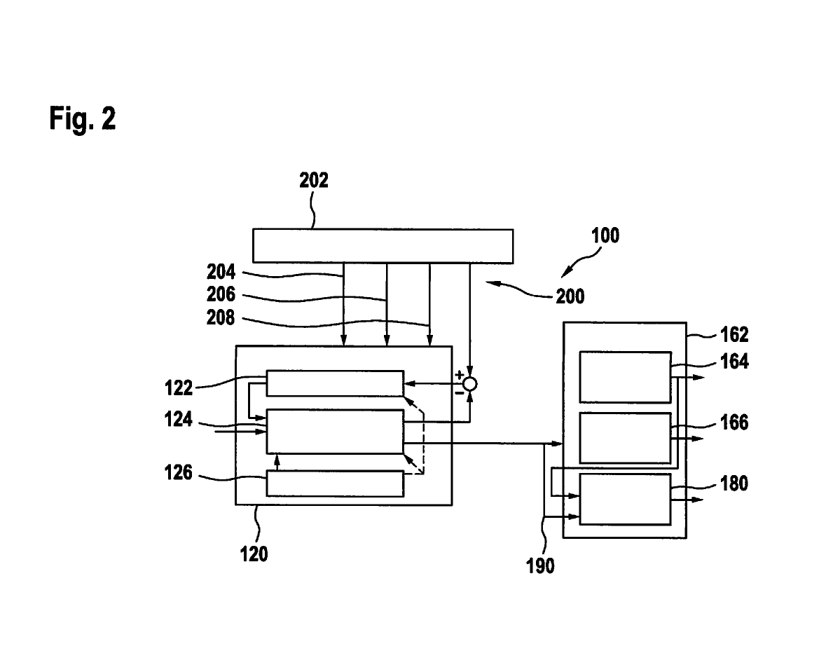

FIG. 2 shows a battery sensor for carrying out the presented method, designated as a whole by reference character 100. This battery sensor 100 is an expansion of battery sensor 10 of FIG. 1. Here, battery sensor 100 is shown in simplified fashion; in principle all components of battery sensor 10 of FIG. 1 are also provided in battery sensor 100 of FIG. 2.

The Figure shows a block 120 for estimating parameters and states. In this block, a feedback unit 122, a battery model 124, and an adaptation 126 of the parameters are provided. In a block 162 that has predictors, a charge predictor 64, a voltage predictor 66, and a first module 180 are provided. In the Figure, first module 180 is shown as representing all the modules. The first module is obligatory, and the other modules can be placed here in any combinations.

In first module 180, the calculation takes place of the instantaneous reliability characteristic quantity/quantities of the battery, such as the probability of failure, trigger for battery exchange, trigger for transition to the safe state or driver takeover.

In order to ascertain the load on the battery, from battery sensor 100 the current SOC and temperature values are given to first module 180 in battery sensor 100, or are given to some other control device (arrow 190). There, the values are stored as SOC curves and temperature curves. Parallel to this, the times of the SOC and temperature measurements are also written as a time curve. The SOC curve is classified online in the control device or battery sensor using rainflow counting, taking time into consideration. Rainflow counting is a method in which, from the curves of a measurement, amplitudes, its center, its start time, and its duration are ascertained. This brings about a conversion of the curve into strokes having the features amplitude, stroke center, start of the stroke, and duration of the stroke. In addition to rainflow counting, there are also other suitable methods.

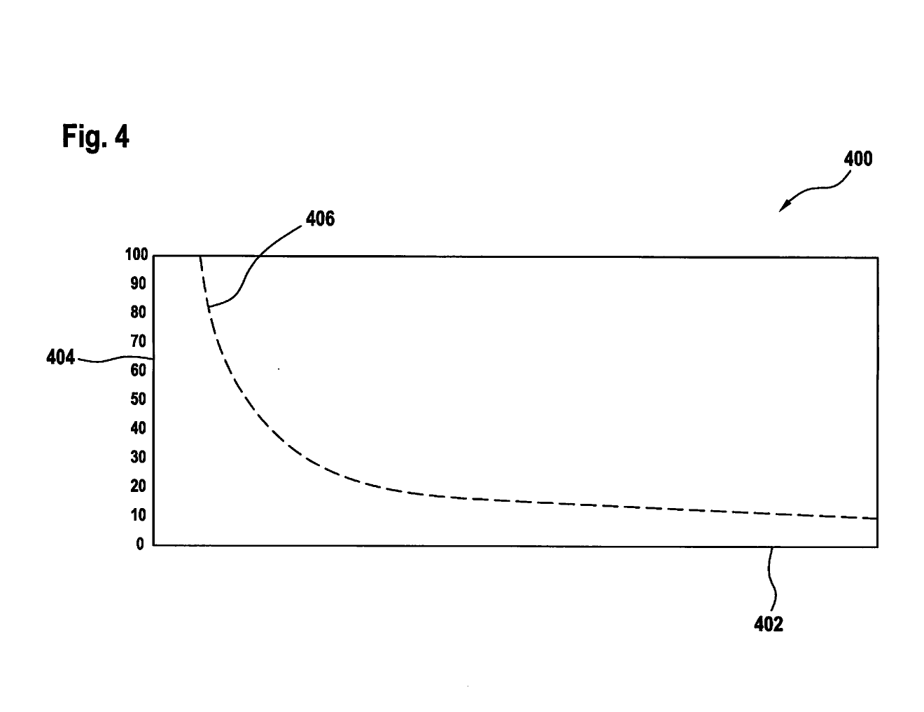

Over the time at which the respective stroke has taken place, a temperature can be assigned to the stroke. Via the slope of the Wöhler curve, as shown in FIG. 4, the respective stroke is recalculated to the defined reference level, e.g. ΔSOC 30% and 25° C., at which the load capacity data are present. Here, the temperature can be taken into account for example via an Arrhenius approach.

In a graphic 400, FIG. 4 shows Wöhler curve N_{f} 406, on whose abscissa 402 the number of cycles is plotted and on whose ordinate 404 ΔSOC [%] is plotted.

Wöhler curve N_{f} indicates what number of cycles, at what stroke, the battery can bear until the failure criterion is reached. The Wöhler curve can be described for example by Equation 1:

N_{f}=α(ΔSOL)^{-p} (1)

Through transformation of this Equation 1, all battery strokes ascertained by the rainflow counting can be recalculated to a reference level.

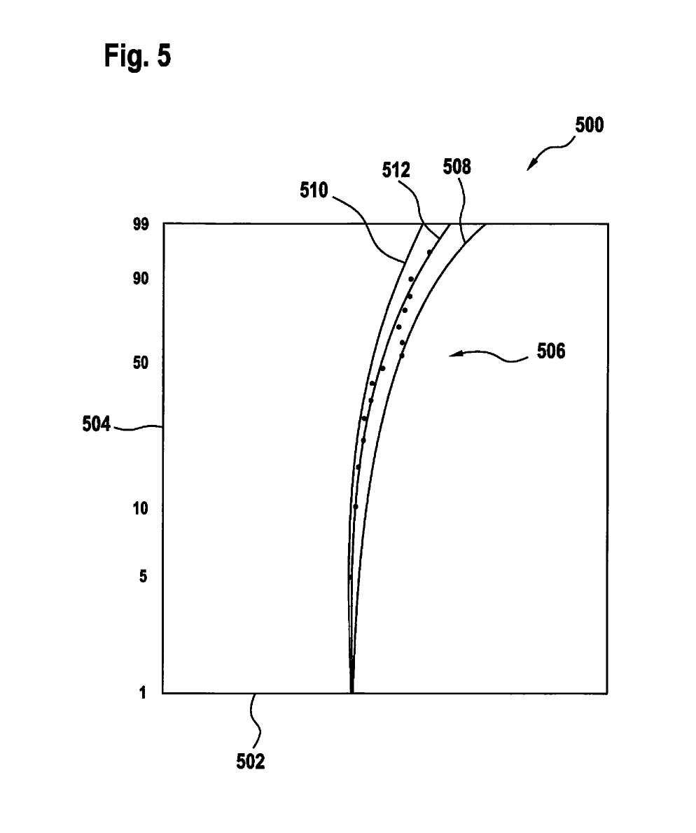

In the load capacity model of the battery, represented in this case by a Weibull distribution, it is plotted what number of battery cycles at the reference level leads to what probability of failure of the battery. By loading the battery at the reference level and using the load capacity model at reference level, the probability of failure of the battery at the current time can thus be calculated online. The Weibull distribution is the most probable distribution; theoretically, other distributions may better describe the failure characteristic. The Weibull distribution is shown in FIG. 5.

In a graphic 500, FIG. 5 shows Weibull distribution 506, on whose abscissa 502 the number of cycles is plotted and on whose ordinate 504 the failure probability [%] is plotted, with a lower line 508 that shows the lower confidence interval, an upper line 510 showing the upper confidence interval, and a line 512 that represents a probability at which 50% of the components fail.

Possible expansions or adaptations are:
implementation of boundary values of the reliability characteristic quantities that introduce the exchange of the battery or the blocking of operating modes, e.g. automated driving, coasting, recuperation, transition to the safe state, and/or driver takeover;
further processing of the ascertained reliability characteristic values in order to ascertain the system reliability characteristic values, e.g. probability of vehicle electrical system failure; here as well operating modes can be blocked and/or a transition to the safe state can be introduced, e.g. via boundary values.

FIG. 2 again shows a second module 200. This module is used to predict an exceeding of the required reliability characteristic quantity/quantities of the battery, the authorization of scenarios, the selection of the safe stop scenario, the trigger for battery exchange, the trigger for a transition to the safe state or driver takeover.

For this purpose, in FIG. 2 an authorization query 202 is shown that comes from the control device. Provided from this device as inputs for block 202 are: a permissible failure probability 204, a current time t_{actual} 206, and a time span Δtᵢₙₜₑᵣᵥₐₗ 208 that is planned for the change of battery, the so-called change interval of the battery.

The task of second module 200 is to predict the reliability characteristic quantities of the battery and to make authorization decisions, or to select safe stop scenarios. Here, the higher-order control device communicates the permissible value of the reliability characteristic quantity, or this is already stored in the control device or in the battery sensor. An example of the permissible reliability characteristic quantity is a particular probability of failure of the battery, or the maintenance of the failure-free time in a three-parameter Weibull distribution.

In second module 200, the load capacity model of the battery is converted from probability of failure over battery cycles at the reference level to probability of failure over the duration of operation. For this purpose, the quotient is formed of the load previously seen and the previous operating duration.

In this second model 200, the change of battery can be predicted with regard to time. For this purpose, it is assumed that the ratio of load and operating duration is constant, and with this approach a linear prediction of the remaining operating time of the battery is made. Approaches are also conceivable that have a non-constant ratio of load and operating duration.

If the predicted remaining operating duration is below a specified boundary value, then the transition to the safe state, or driver takeover, can be introduced early, so that a critical vehicle state is avoided.

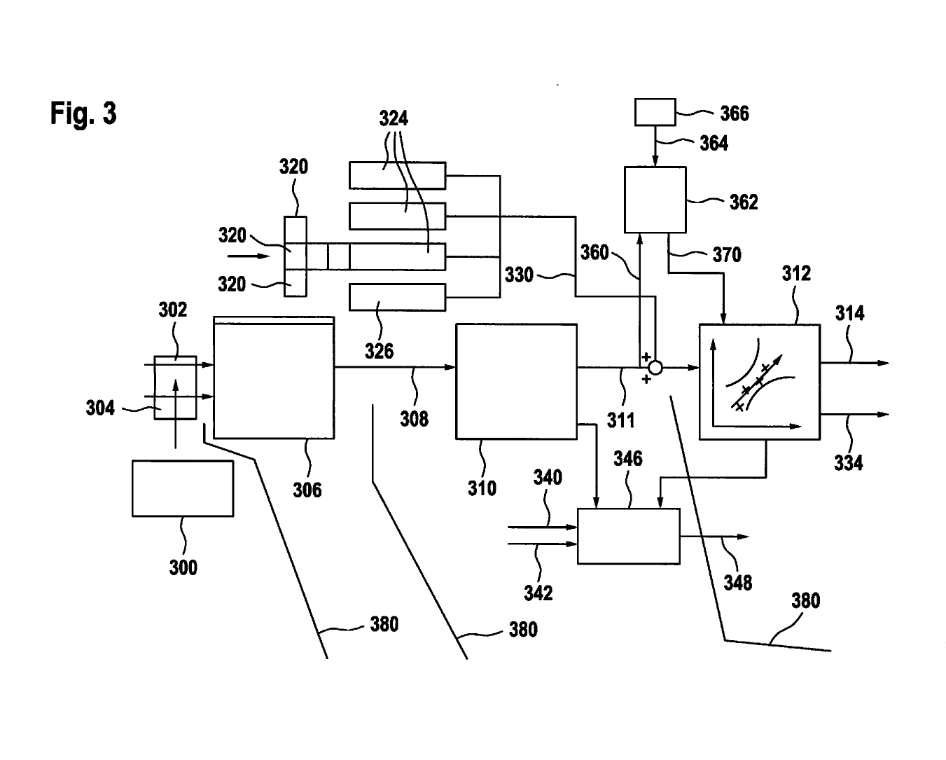

In a flow diagram, FIG. 3 illustrates a possible sequence of the method using all four modules.

Concerning the first module:

In a storage element 300, curves of SOC 302 and temperature T 304 over time are stored. These curves are classified using rainflow counting 306. A resulting rainflow matrix 308 is recalculated to a reference level using a Wöhler curve 310. This yields the number of reference cycles. The calculation of a probability of failure F(n) 314 takes place using a load capacity model 312, in this case the Weibull distribution.

Concerning the second module:

A number of possible errors 320 can be combined with possible scenarios 324, in particular start-stop scenarios, and conditions 326, resulting in reference cycles 330 which are added to the number 311. From the Weibull distribution 312, there then additionally results a prediction 334 of various scenarios. The output is done as a vector.

In addition, time t_{actual} 340 and the time interval until the next change Δtᵢₙₜₑᵣᵥₐₗ 342 are automatically inputted to a block 346 in which battery cycles are converted into time cycles. In this way, the Weibull distribution can be converted from the probability of failure over battery cycles at the reference level into the probability of failure over time. The probability of failure until the next change interval continues to result at output 348 in accordance with F(t′=Δtᵢₙₜₑᵣᵥₐₗ+t).

Concerning the third module:

In this module, the Weibull distribution or load capacity model 312 can be adapted. For this purpose, a degree of damage at reference level 360, based on the SOC, is subjected to an extrapolation 362. Here, SOH 364 continues to be taken into account by battery sensor 366. This yields a new failure-free time to 370, or a correction factor for the Weibull distribution or for the load capacity model 312.

Fourth module 380 is illustrated using lines that indicate at what times, or after what step, a cloud could be included.

Concerning the authorization decisions, the following is stated:

It is checked online, in the calculating control device or in the battery sensor, which scenarios are permissible and which are not, from the point of view of reliability. Here, for each scenario the number of required reference cycles per operating duration can be stored. Alternatively, this value can also be ascertained online through simulation of the respective scenarios and calculation in accordance with “first module, load.” Depending on the result, the authorization is granted, is granted for a particular time span, or is not granted. The result is communicated to the higher-level control device for example in the form of an authorization vector.

Examples of scenarios that have an influence on the damage to the battery and whose authorization is checked are:
Operating modes (manual travel, automated travel, coasting, recuperation, . . . )
Operating strategies

In the authorization, the following cases can be distinguished:

Case I: higher-level control device queries the operating mode and its duration, i.e. the operating strategy is known.

Example: the driver inputs a destination to the navigation device, and the system control then makes a query concerning the authorization of operating modes and their duration.

For the queried parameters, namely duration, operating mode, and operating strategy, the “required” reference cycle number is ascertained and is added to the previously seen load at the reference level. It is now checked whether the defined reliability boundary value is maintained. If it is maintained, then the queried case is authorized; otherwise not.

Case II: the higher-level control device generally continuously queries the battery sensor or calculating control device, or the battery sensor or calculating control device continuously reports remaining durations for all the operating modes to the higher-level control device.

In case II, for all possible combinations of operating modes and operating strategies the duration until the defined reliability boundary value is reached is ascertained and is communicated to the higher-level control device. Thus, the time durations are available specifying in each case how long driving is to be permitted to take place, and there is a time-limited authorization of the functions. If the vehicle is in a combination of operating mode and operating strategy in which battery failure is soon impending, then a change can be made to a combination that better protects the battery, or the transition to the safe state or driver takeover can be introduced.

Concerning the choice of the safe stop scenario, the following is stated:

It is checked online, in the calculating control device or battery sensor, which safe stop scenarios are permissible and which are not from the point of view of reliability. Here, for each scenario the number of required reference cycles can be stored. Alternatively, this value can also be ascertained online through simulation of the respective scenarios and calculation in accordance with “module I, load.”

Possible parameters influencing the choice of the safe stop scenario are:
safe stop scenario (stopping in the lane, driving on the right shoulder, . . . )
errors (vehicle electrical system errors) recognized in the vehicle energy network
operating strategy.

Case I: higher-level control device queries safe stop scenario(s) with known operating strategy and identified errors.

For the queried combination of safe stop scenario, vehicle electrical system errors, and operating strategy, the required reference cycle number is ascertained. This is added to the previous load at the reference level and it is checked whether the defined reliability boundary value is maintained. If this is the case, then the combination is authorized, e.g. as a result vector to the higher-level control device.

Case II: the higher-level control device generally continuously queries the battery sensor or calculating control device, or the battery sensor or calculating control device continuously reports possible safe stop scenarios, combined with operating modes and error cases in the vehicle electrical system, and in this way results of the error injection simulation at the vehicle electrical system level are obtained.

For all possible combinations of safe stop scenario, vehicle electrical system error, and operating strategy, the required reference cycle number is ascertained. For each combination, the required reference cycle number is added to the previous load at the reference level, and it is checked whether the defined reliability boundary value is maintained. If this is the case, then the combination is authorized. This procedure is repeated for each combination and the result is communicated to the higher-level control device, e.g. in the form of a solution vector.

The third module has the task of also writing the reference value of the actual degree of aging of the battery (SOH—loss of capacity) and extrapolating its curve over the operation duration or the experienced load until the failure criterion is reached, e.g. capacity loss of 20%. Through the value obtained in this way, the quality of the battery compared to the total population of batteries can be taken into account, and the previously used load capacity model can be adapted to the battery quality, e.g. through redefinition of the failure-free time or a correction factor.

The fourth module uses the prediction in order to correct the load capacity model. For this purpose, the fourth module supplies the damage experienced by the battery (SOH) via load, and supplies the value extrapolated therefrom (see third module) to a cloud storage unit. There, the load capacity module is optimized on the basis of the multiplicity of damage via load data or extrapolated values, and is sent back to the fourth module. In this way, the basic load capacity module is continuously improved.

Optionally, the following may be provided:
the fourth module now knows the quality of the installed battery compared to the population, and can take into account the quality of the battery, e.g. via a “correction factor”;
in the case of battery errors that first occur in the field, the authorization of the operating modes that cause error can be refused via the cloud until the error is remedied, e.g. through an exchange, thus avoiding failure and the resulting critical vehicle state.

Further advantages due to the exchange with the cloud are:
realistic battery loading is obtained for future component or system developments/designs;
adaptation of the operating strategy via the cloud (goal: optimal exploitation of components);
if a battery exchange is coming up soon due to regular maintenance (predicted battery operating duration is not sufficient to last until the next maintenance), but the battery can still bear load, the operating strategy is selected so that the battery is more strongly loaded in order to protect other components, e.g. DC/DC converter;
automated communication with the repair facility if predicted battery lifespan is about to expire, in order to exchange components;
prediction of the load through knowledge of the route profile, on the basis of navigation data (start-destination route guidance).

The presented method thus enables the, if warranted, cloud-based derivation of changes to the operating strategies in order to reduce battery failures. This enables a balanced operating strategy, taking into account all relevant vehicle electrical system components.

In this way, an improvement can be achieved in component and system development, and their design, through field data acquisition. An improvement in the load capacity models based on a large number of components in the field is also possible, e.g. through deep learning. In addition, an improvement in the load models based on known, real component loads can be achieved.

The method and the system can be used in any vehicle in which the probability of failure of the components and/or a system reliability analysis are to be implemented. In principle, their use is possible in any vehicle in which the authorization of particular functions, or the choice of the reaction to error (safe stop scenario), is to be done as a function of the predicted behavior (on the basis of the previous load).

The use of the method and system can be provided in all vehicles in which the vehicle electrical system has a high degree of safety relevance, such as vehicles having coasting operation, recuperation, or automated vehicles. In addition, the method and system may conceivably be used in vehicles having electrical brake boosting (iBooster, IPB). It is to be noted that efforts are currently being made to move away from kilometer-based or time interval-based maintenance towards state-based maintenance. The presented method can also be used for such state-based maintenance.

The evaluation algorithm described herein, implemented by the method, can be carried out in a battery sensor, a control device, or in a computer in the vehicle or outside the vehicle, e.g. in a cloud. Because the battery temperature has a large influence on battery damage, reliability, and lifespan, for example the ambient external temperature and further temperature predictions can be integrated into the analysis, for example using destination information from the navigation device, in order to enable a more precise prediction of a battery failure.

The analysis of the battery damage can take place in segments, for example as a function of the month, in order to ascertain the damage in the respective segment and to enable better prediction of service intervals and failures. In this way, influences such as temperature are taken into account with greater precision. Comparisons of the predictions for the coming days can also be taken into account in this way.

1.-13. (canceled)

14. A method for monitoring a battery in a motor vehicle, comprising:
controlling a first module to ascertain an operating quantity of the battery; and
comparing a variable that represents the operating quantity with a load capacity model in order to ascertain a quantity characterizing a reliability of the battery, so that a future behavior of the battery can be predicted.

15. The method as recited in claim 14, further comprising ascertaining the variable by converting the operating quantity.

16. The method as recited in claim 14, wherein the variable corresponds to the operating quantity.

17. The method as recited in claim 14, wherein the operating quantity is provided at least partially by a battery sensor.

18. The method as recited in claim 14, further comprising implementing a boundary value for a reliability characteristic quantity.

19. The method as recited in claim 18, further comprising processing the ascertained reliability characteristic quantity in order to ascertain a system reliability characteristic value.

20. The method as recited in claim 14, further comprising controlling a second module to evaluate and, if warranted, authorize a scenario.

21. The method as recited in claim 14, further comprising controlling a second module to compare a load capacity model with an extrapolation of an actual SOH, and, if warranted, adapt the load capacity model.

22. The method as recited in claim 14, further comprising controlling a second module to compare an SOH with at least one central database.

23. The method as recited in claim 22, wherein the second module compares the SOH with the central database by implementing a comparison with a cloud.

24. A system for monitoring a battery in a motor vehicle, comprising:
an arrangement for controlling a first module to ascertain an operating quantity of the battery; and
an arrangement for comparing a variable that represents the operating quantity with a load capacity model in order to ascertain a quantity characterizing a reliability of the battery, so that a future behavior of the battery can be predicted.

25. The system as recited in claim 24, wherein the system is implemented in a battery sensor.

26. The system as recited in claim 24, wherein the system is set up to carry out a cloud-based processing of data.
